(19) United States
(12) Patent Application Publication
(10) Pub. No.: US 2011/0120548 A1
(43) Pub. Date: May 26, 2011

(54) SOLAR CELL STRUCTURE AND METHOD OF MAKING

(75) Inventors: Bing-Cyun CHEN, Xizhuang City (TW); Ching-Hsi LIN, Hsinchu City (TW); Chen-Hsun DU, Taipei City (TW); Chung-Wen LAN, Xindian City (TW)

(73) Assignee: INDUSTRIAL TECHNOLOGY RESEARCH INSTITUTE, Hsinchu (TW)

(21) Appl. No.: 12/950,515

(22) Filed: Nov. 19, 2010

(30) Foreign Application Priority Data
Nov. 20, 2009 (TW) 98139569

(51) Int. Cl. H01L 31/0224; H01L 31/18

(52) U.S. Cl. 136/256; 438/98; 438/72; 257/E31.124; 257/E31.119

(57) ABSTRACT

A solar cell structure includes a semiconductor substrate, a first electrode, a second electrode and at least one via extending through the semiconductor substrate. The first electrode is located in the at least one via, and includes a glass phase and lead oxide, wherein the lead oxide is present in a first weight percentage amount relative to the weight of the glass phase of the first electrode. The second electrode includes a glass phase and lead oxide, and covers the first electrode, wherein the lead oxide of the second electrode is present in a second weight percentage amount relative to the weight of the glass phase of the second electrode. The first weight percentage amount is less than the second weight percentage.

### CROSS-REFERENCE TO RELATED APPLICATION

This application claims the priority benefit of Taiwan application serial no. 98139569, filed

Nov. 20, 2009. The entirety of the above-mentioned patent application is hereby incorporated by reference herein and made a part of specification.

### TECHNICAL FIELD

The disclosure relates to a solar cell, and more particularly, to a metal wrap through (MWT) solar cell. The disclosure also relates to a method of making a solar cell, and more particularly, to a method of making an MWT solar cell.

### BACKGROUND

Reducing an electrode shielding area on a front side (that is, a light incident side) of a solar cell is the most direct way of enhancing the efficiency of the solar cell, and this consequently leads to the development of a back side electrode. The structures of solar cells are mainly categorized into interdigitated, emitter wrap through (EWT), and metal wrap through (MWT) back contacts.

In the MWT back contact solar cell, vias of the semiconductor substrate are filled with metal, so that electrons collected by the light incident side are directed to the back side of the solar cell. A front side electrode and an intra-via electrode are generally formed with an electrically conductive adhesive. The electrically conductive adhesive includes about 60-80 wt % of silver powder, about 5 wt % of glass frit, and about 15-35 wt % of organic carrier. Herein, silver powder is the main material for conduction of the electrode, glass frit is the main adhesive, and organic carrier facilitates a screen printing process. Glass frit softens in a high temperature sintering process, and silver and silicon are then melted and/or dissolved into the softened or liquefied glass. Afterwards, silver and silicon are precipitated in a cooling process. As a consequence, silver obtains superior adhesion on silicon, such that a better contact is established between the electrode and the semiconductor substrate. Adding lead (Pb) to glass frit in an electrically conductive adhesive might reduce the softening point and the viscosity coefficient of glass for the softened glass to flow more easily. Therefore, the solubility of silver and silicon is enhanced, so that a better contact is established between the electrode and the semiconductor substrate.

Currently, a method of fabricating the MWT back contact solar cell using a co-firing process is disclosed, for example, in “Industrially feasible multi-crystalline metal wrap through (MWT) silicon solar cells exceeding 16% efficiency” published by Florian Clement et al. on P.1051-1055 of Solar Energy Materials & Solar Cells 93 (2009), which is incorporated by reference herein in its entirety. The method mainly adopts a co-firing process to fabricate the front side electrode and the intra-via electrode.

However, the inventor has discovered that in the high temperature sintering (co-firing) process, the electrically conductive adhesive usually penetrates an insulating layer between the intra-via electrode and the semiconductor substrate so as to result in short-circuit.

### SUMMARY

The disclosure is directed to a solar cell structure, a pre-firing solar cell structure and a method of making a solar cell structure.

In one or more embodiments, a solar cell structure includes a semiconductor substrate, a first electrode, and a second electrode. The semiconductor substrate includes a first type semiconductor layer having a first side and a second side, a second type semiconductor layer on the first side of the first type semiconductor layer, and at least one via extending through the semiconductor substrate. The first electrode is located in the at least one via, and includes a glass phase and lead oxide, wherein the lead oxide is present in a first weight percentage amount relative to the weight of the glass phase of the first electrode. The second electrode includes a glass phase and lead oxide, and is partially disposed on the second type semiconductor layer and covers the first electrode, wherein the lead oxide of the second electrode is present in a second weight percentage amount relative to the weight of the glass phase of the second electrode. The first weight percentage amount is less than the second weight percentage amount.

In one or more embodiments, a pre-firing solar cell structure includes a first type semiconductor substrate, a second type semiconductor layer, a pre-firing first electrode, a pre-firing second electrode, and an insulating layer. The first type semiconductor substrate has a first side, a second side, and at least one via extending through the first type semiconductor substrate. The second type semiconductor layer is at least partially disposed on the first side of the first type semiconductor substrate. The pre-firing first electrode is located in the at least one via and includes glass frit and lead oxide, wherein the lead oxide is present in a first weight percentage amount relative to the weight of the glass frit of the pre-firing first electrode. The pre-firing second electrode includes glass frit and lead oxide, and is disposed on the second type semiconductor layer and covers the pre-firing first electrode, wherein the lead oxide of the pre-firing second electrode is present in a second weight percentage amount relative to the weight of the glass frit of the pre-firing second electrode. The insulating layer is at least partially disposed between a sidewall of the at least one via and the pre-firing first electrode. The first weight percentage amount is less than the second weight percentage amount.

In a method of making a solar cell structure in accordance with one or more embodiments, at least one via is formed through a first type semiconductor substrate having a first side, a second side, and a second type semiconductor layer on the first side of the first type semiconductor substrate. An insulating layer is formed on a sidewall of the at least one via and the second side of the first type semiconductor substrate. A pre-firing first electrode is formed in the at least one via. The pre-firing first electrode includes glass frit and lead oxide, wherein the lead oxide is present in a first weight percentage amount relative to the weight of the glass frit of the pre-firing first electrode. A pre-firing second electrode is formed on the second type semiconductor layer to cover the pre-firing first electrode. The pre-firing second electrode includes glass frit and lead oxide, wherein the lead oxide of the pre-firing second electrode is present in a second weight percentage amount relative to the weight of the glass frit of the pre-firing second electrode. The first weight percentage amount is less than the second weight percentage amount.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional view of a solar cell structure according to one or more embodiments of the disclosure.

FIGS. 2A-2E are cross-sectional views of a solar cell structure being manufactured in a manufacturing method according to one or more embodiments of the disclosure.

FIG. 3 is a graph showing Voc-Jsc characteristics of various solar cells.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

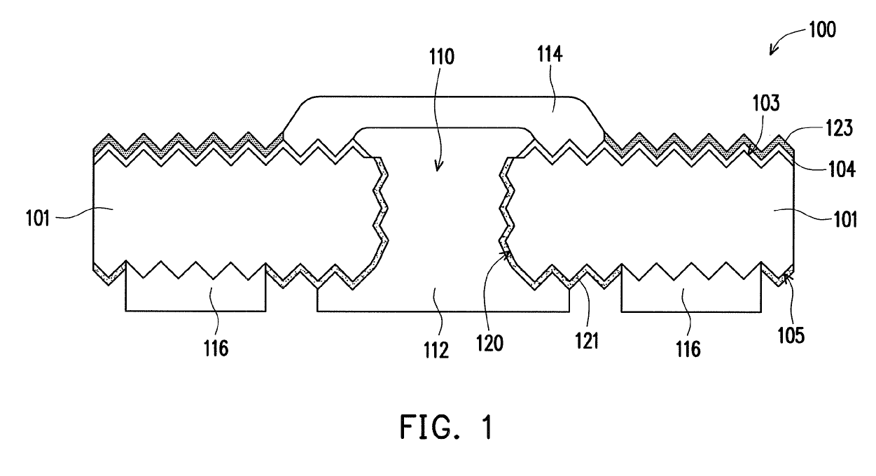

FIG. 1 is a cross-sectional view of a solar cell structure according to one or more embodiments of the disclosure.

Referring to FIG. 1, a solar cell structure 100 includes a semiconductor substrate 101, a first electrode 112, and a second electrode 114. The semiconductor substrate 101 includes a first type semiconductor layer having a first side 103 and a second side 105, a second type semiconductor layer 104 on the first side 103 of the first type semiconductor layer, and at least one via 110 extending through the semiconductor substrate 101.

In some embodiments, the first type semiconductor layer includes a p-type semiconductor layer and the second type semiconductor layer 104 includes a n-type semiconductor layer. In further embodiments, the first type semiconductor layer includes an n-type semiconductor layer and the second type semiconductor layer 104 includes a p-type semiconductor layer.

In some embodiments, the surface of the semiconductor substrate 101 is a textured surface, such as the one shown in FIG. 1 as zigzagging along the first side 103 and the second side 105. Such zigzagging pattern is configured, for example, to enhance absorption of sunlight.

The first electrode 112 is located in the at least one via 110 of semiconductor substrate 101 and includes a glass phase and lead oxide, wherein the lead oxide is present in a first weight percentage amount relative to the weight of the glass phase of the first electrode. The upper surface of the first electrode 112, in some embodiments, is substantially coplanar with the second type semiconductor layer 104 of the semiconductor substrate 101.

The second electrode 114 includes a glass phase and lead oxide, and is partially disposed on the second type semiconductor layer 104 and covers the first electrode 112, wherein the lead oxide of the second electrode is present in a second weight percentage amount relative to the weight of the glass phase of the second electrode.

It is noted that the first weight percentage amount is less than the second weight percentage amount.

In some embodiments, the first electrode and the second electrode have the same weight percentage amount of glass phase relative to the weight of the first electrode and the second electrode, respectively.

In some embodiments, the first weight percentage amount is 20 wt % or less and, in at least one embodiment, ranges from 0.1 to 15 wt %. The second weight percentage amount, in some embodiments, is greater than 20 wt % and, in at least one embodiment, is more than 50 wt %.

In some embodiments, the first electrode and/or the second electrode further include(s) a conductive component of a highly conductive material, e.g., a metal, such as Ag, Au, Cu or Pt.

In some embodiments, the first electrode 112 is free or essentially free of lead oxide.

The solar cell structure 100 further includes an insulating layer 121, a third electrode 116 and an anti-reflective layer 123 disposed on the second type semiconductor layer 104.

The insulating layer 121 is disposed between a sidewall 120 of the semiconductor substrate 101 near the at least one via 110 and the first electrode 106. That is, the first electrode 112 and the semiconductor substrate 101 are electrically isolated by the insulating layer 121. In some embodiments, the material of the insulating layer 121 includes silicon nitride.

The third electrode 116 is disposed on a portion of the second side 105 of the first type semiconductor layer. The material for forming the third electrode 116 includes an aluminum paste.

In some embodiments, the insulating layer 121 is further disposed on the second side 105 of the first type semiconductor layer in a region not covered by the third electrode 116.

In some embodiments, the second electrode 114 is partially disposed on the second type semiconductor layer 104 and covers the first electrode 112. That is, the second electrode 114 is electrically connected to the first type semiconductor layer through the second type semiconductor layer 104.

In one or more embodiments, the anti-reflective layer 123 is disposed on the second type semiconductor layer 104 in a region not covered by the second electrode 114. The material for the anti-reflective layer 123 includes silicon nitride, for example.

In some embodiments, at least two out of three electrodes, e.g., the first electrode 112, the second electrode 114, and the third electrode 116, are fabricated simultaneously through a co-firing process.

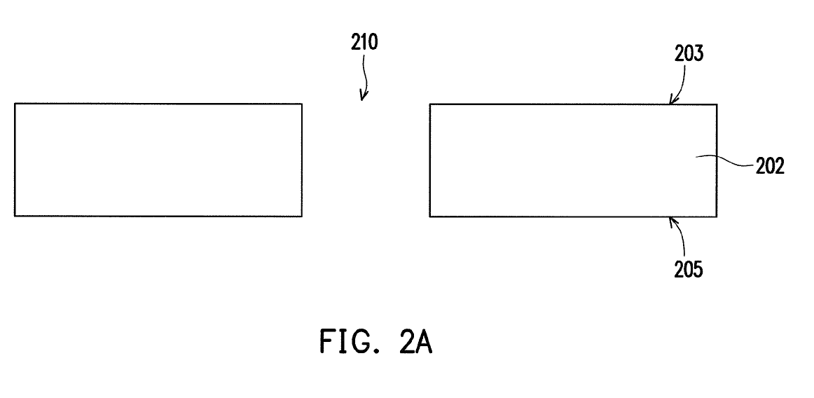

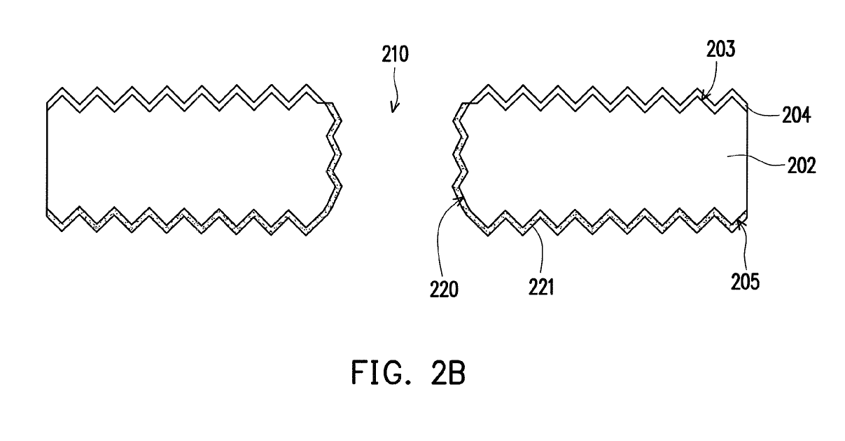

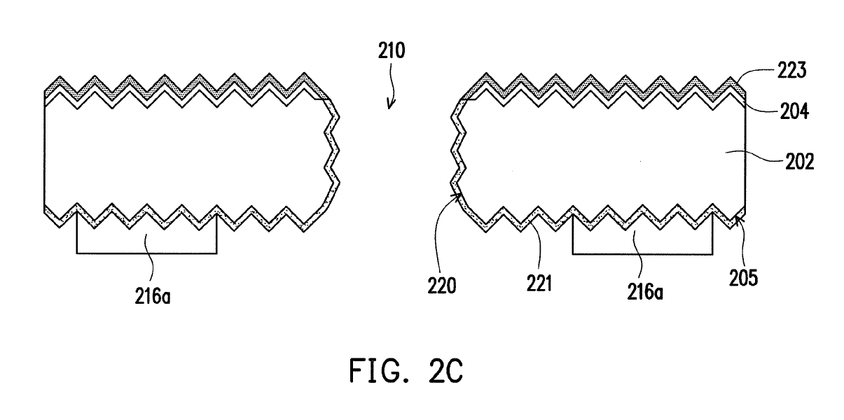

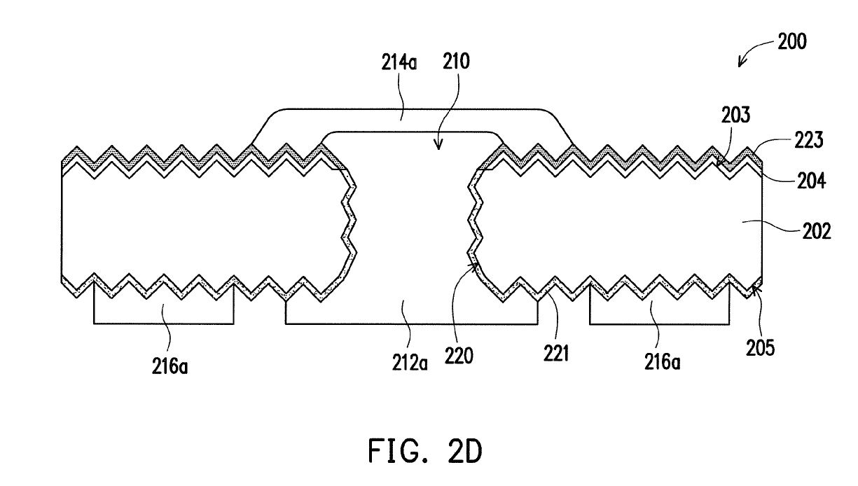

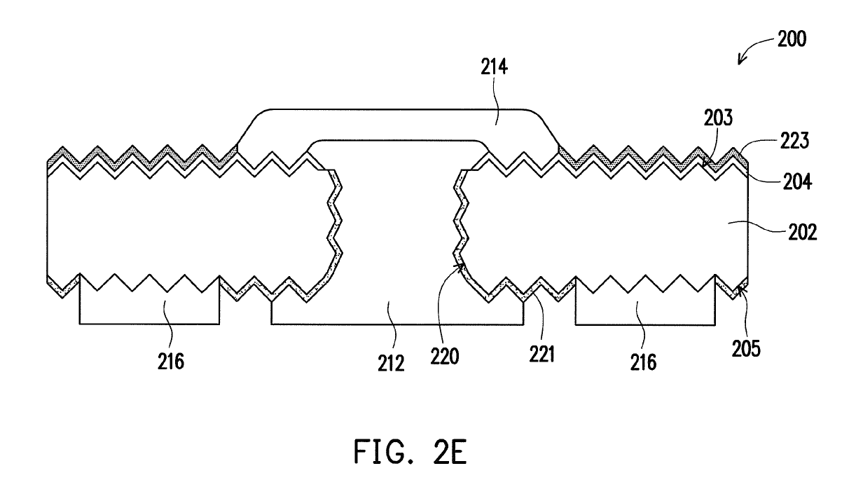

A method of fabricating the solar cell structure in accordance with one or more embodiments of the disclosure is explained hereinafter. FIGS. 2A-2E are schematically cross-sectional views of a solar cell structure being manufactured by such a method.

Referring to FIG. 2A, a semiconductor substrate 202 includes a first type silicon semiconductor, for example, a p-type semiconductor in some embodiments or an n-type in other embodiments. In some embodiments, the semiconductor substrate 202 includes silicon. The semiconductor substrate 202 has a first side 203 and a second side 205. A via 210 is formed in the semiconductor substrate 202 by performing, in some embodiments, a laser drilling process.

Referring to FIG. 2B, a surface texturing process is performed on the semiconductor substrate 202 to form a textured surface, such as the one shown in FIG. 2B as zigzagging along the first side 203, the second side 205 and the sidewall 220 of the semiconductor substrate 202 near the via 210. The surface texturing process, in some embodiments, is performed by utilizing a potassium hydroxide (KOH) solution, for instance.

Thereafter, an insulating layer 221 is formed on the sidewall 220 of the semiconductor substrate 202 near via 210 and the second side 205 of the semiconductor substrate 202. The insulating layer 221 in some embodiments includes silicon nitride and is formed by performing, for instance, a plasma-enhanced chemical vapor deposition (PECVD) process.

Afterwards, a second type semiconductor layer 204 is formed on the first side 203 of the semiconductor substrate 202. The conductivity type of the second type semiconductor layer 204 is opposite to that of the semiconductor substrate 202, and is, for instance, an n-type semiconductor layer. The second type semiconductor layer 204 is formed in some embodiments by implementing a diffusion process using an n-type phosphorus oxychloride (POCl₃) gas.

Referring to FIG. 2C, an anti-reflective layer 223 is subsequently formed on the second type semiconductor layer 204. The anti-reflective layer 223, in some embodiments includes silicon nitride, for example, and is formed by a PECVD process.

Next, a pre-firing third electrode 216a is coated on the insulating layer 221 on the second side 205 of the semiconductor substrate 202. The method of coating the pre-firing third electrode 216a in some embodiments includes performing a screen printing process, for example. The pre-firing third electrode 216a in some embodiments includes an aluminum paste.

Referring to FIG. 2D, a pre-firing first electrode 212a is coated to at least partially fill the via 210. In some embodiments, pre-firing first electrode 212a is filled in the via 210 from the second side 205 of the semiconductor substrate 202. In some embodiments, the pre-firing first electrode 212a completely fills the via 210 and in some embodiments covers a portion of the second side 205 of the semiconductor substrate 202. The pre-firing first electrode 212a includes a glass frit and lead oxide, wherein the lead oxide is present in a third weight percentage amount relative to the weight of the glass frit of the pre-firing first electrode 212a. In some embodiments, the upper surface of the pre-firing first electrode 212a is substantially coplanar with the second type semiconductor layer 204.

The method of coating the pre-firing first electrode 212a in some embodiments includes performing a screen printing process.

Then, a pre-firing second electrode 214a is coated on the pre-firing first electrode 212a and covers, if it is present, a portion of the anti-reflective layer 223 around the via 210. In some embodiments, not shown, the pre-firing second electrode 214a covers the second type semiconductor layer 204 around the via 210. The pre-firing second electrode 214a includes a glass frit and lead oxide, wherein the lead oxide is present in a fourth weight percentage amount relative to the weight of the glass frit of the pre-firing second electrode 214a. The method of coating the pre-firing second electrode 214a in some embodiments includes performing a screen printing process.

In some embodiments, the pre-firing first electrode 212a and/or the second electrode 214a further include(s) a conductive component of a highly conductive material, e.g., a metal, such as Ag, Au, Cu or Pt.

The third weight percentage amount is lower than the fourth weight percentage amount.

In some embodiments, the third weight percentage amount is 20 wt % or less and, in at least one embodiment, ranges from 0.1 to 15 wt %. The fourth weight percentage amount in some embodiments is greater than 20 wt % and, in at least one embodiment, is more than 50 wt %.

A pre-firing solar cell structure 200 is thus completed as exemplarily illustrated in FIG. 2D. In some embodiments, the pre-firing third electrode 216a and/or the anti-reflective layer 223 is/are omitted from the pre-firing solar cell structure 200.

Thereafter, referring to FIG. 2E, a co-firing process is performed to sinter the pre-firing first electrode 212a into a first electrode 212, to sinter the pre-firing second electrode 214a into a second electrode 214, and to sinter the pre-firing third electrode 216a into a third electrode 216, thereby completing the fabrication of the solar cell structure.

In some embodiments where the pre-firing third electrode 216a is not yet included in the pre-firing solar cell structure 200, such pre-firing third electrode 216a is coated and fired separately after the co-firing of the first and second electrodes 212, 214.

In some embodiments, one or more of the above described steps is/are omitted or performed in other orders not specifically disclosed. For example, in one or more embodiments, the coating the pre-firing third electrode is performed after the coating of the pre-firing first and/or second electrode(s).

It is noted that in the co-firing process, since the third weight percentage amount of lead oxide relative to the weight of the glass frit of the pre-firing first electrode 212a is lower than the fourth weight percentage amount of lead oxide relative to the weight of the glass frit of the pre-firing second electrode 214a, the pre-firing second electrode 214a thus has a lower glass softening temperature, a longer reaction time during the sintering, and, hence, a better penetrating effect than the pre-firing first electrode 212a. Consequently, the second electrode 214 is capable of penetrating the anti-reflective layer 223 covered by pre-firing second electrode 214a, so that the second electrode 214 is electrically connected to the semiconductor substrate 202 through the second type semiconductor layer 204. On the other hand, the pre-firing first electrode 212a has a higher glass softening temperature, a shorter reaction time during the sintering, and, hence, a lesser penetrating effect than the pre-firing second electrode 214a. Consequently, the first electrode 212 is not capable of penetrating the insulating layer 221 on the sidewall 220 of the semiconductor substrate 202 near via 210. Therefore, short-circuit caused by the first electrode 212 penetrating (“firing-through”) the insulating layer 221 is prevented.

In some embodiments, the penetrating effect of the second electrode 214 is ensured when the fourth weight percentage amount of lead oxide relative to the weight of the glass frit of the pre-firing second electrode 214a is sufficiently high, e.g., when the fourth weight percentage amount is greater than 20 wt %, especially, more than 50 wt %.

On the other hand, in some embodiments, the short-circuit prevention effect of the first electrode 212 is ensured when the third weight percentage amount of lead oxide relative to the weight of the glass frit of the pre-firing first electrode 212a is sufficiently low, e.g., when the third weight percentage amount is 20 wt % or less, especially, from 0.1 to 15 wt %.

Moreover, in the co-firing process, the pre-firing third electrode 216a (e.g., aluminum paste) for forming the third electrode 216 also penetrates the insulating layer 221 between the third electrode 216 and the semiconductor substrate 202, such that the third electrode 216 electrically connects to the semiconductor substrate 202.

The glass frit in the pre-firing first and second electrodes functions as an adhesive. In some embodiments where the pre-firing first electrode 212a and the pre-firing second electrode 214a have the same glass frit content, the first electrode 212 and the second electrode 214 have good adhesion to the silicon surface of the semiconductor substrate 202, such that the electrodes are not falling off in the subsequent wiring process. Next, several experimental examples and a comparative example will be described below to emphasize the disclosed effects.

### Experimental Example 1

A laser drilling process was performed in a p-type silicon semiconductor substrate, having a first side and second side, to form a via through the semiconductor substrate (as disclosed with respect to FIG. 2A). The surface of the semiconductor substrate was textured by applying a KOH solution (as disclosed with respect to FIG. 2B). Next, a PECVD process was performed on the sidewall of the via and the second side of the semiconductor substrate to form a silicon nitride insulating layer (as disclosed with respect to FIG. 2C). Afterwards, a diffusion process was implemented using a POCl₃ gas to form an n-type semiconductor layer on the first side of the semiconductor substrate (as disclosed with respect to FIG. 2C). Later, a PECVD process was performed on the first side of the semiconductor substrate to form a silicon nitride anti-reflective layer (as disclosed with respect to FIG. 2C). A screen printing process was implemented on the second side of the semiconductor substrate to coat an aluminum paste (as disclosed with respect to FIG. 2C). A pre-firing first electrode for forming the first electrode was coated on the second side of the semiconductor substrate to at least fill the via (as disclosed with respect to FIG. 2D). The pre-firing first electrode included a glass frit and lead oxide, wherein the lead oxide was present in a 0.01 weight percentage amount relative to the weight of the glass frit of the pre-firing first electrode. A pre-firing second electrode for forming the second electrode was coated on the pre-firing first electrode (as disclosed with respect to FIG. 2D). The pre-firing second electrode included a glass frit and lead oxide, wherein the lead oxide of the pre-firing second electrode was present in a 50 weight percentage amount relative to the weight of the glass frit of the pre-firing second electrode. The pre-firing first and second electrodes further included a silver paste as the conductive component. Subsequently, a co-firing process was performed, e.g., at 400° C. or more, to sinter the pre-firing first electrode filling the via into the first electrode, to sinter pre-firing second electrode into the second electrode, and to sinter the aluminum paste into a third electrode (as disclosed with respect to FIG. 2E) to complete the fabrication of an MWT back contact solar cell.

### Experimental Example 2

An MWT back contact solar cell was fabricated similarly to Experimental Example 1, except that lead oxide was present in a 13 weight percentage amount relative to the weight of the glass frit of the pre-firing first electrode.

### Comparative Example

A comparative solar cell was fabricated similarly to Experimental Example 1, except that the same pre-firing electrode was adopted to form both the first electrode and the second electrode, wherein the lead oxide was present in a 50 weight percentage amount relative to the weight of the glass frit of the pre-firing electrode.

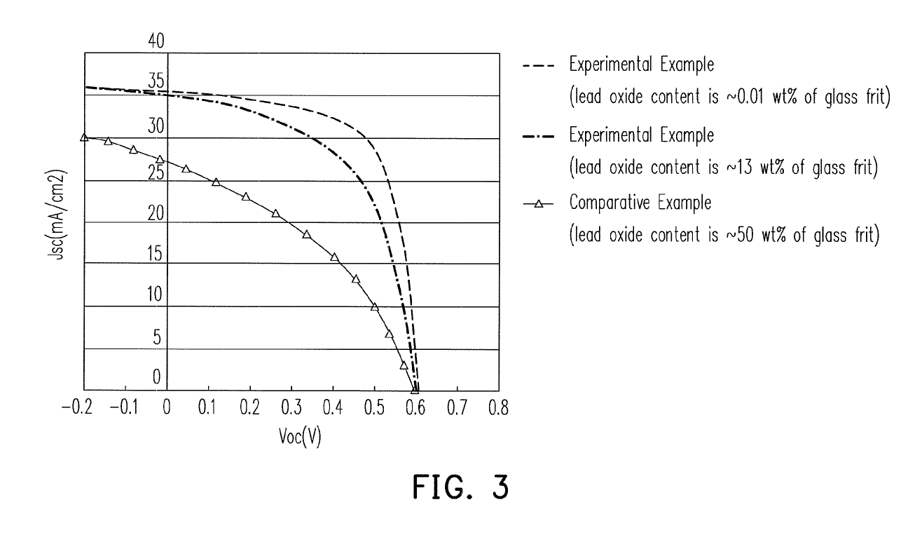

Table 1 and FIG. 3 show a comparison result of the features of the solar cells fabricated from the above Experimental Examples 1, 2 and the Comparative Example, where V_{OC} represents an open circuit current, J_{SC} represents a short circuit current, F.F. is a fill factor, and Eff is a solar cell efficiency, which represent the performance of the respective solar cell.

TABLE 1

| | | Jsc | | |
|---|---|---|---|---|
| | Voc [V] | [mA/cm2] | F.F. | Eff [%] |
| Experimental Example 1 | 0.608 | 35.33 | 66.77 | 14.34 |
| (PbO/glass frit~0.01%) | | | | |
| Experimental Example 2 | 0.600 | 35.15 | 55.41 | 11.69 |
| (PbO/glass frit~13%) | | | | |
| Comparative Example (PbO/glass | 0.595 | 26.92 | 39.33 | 6.30 |
| frit~50%) | | | | |

If the intra-via (first) electrode penetrates the insulation layer on the sidewall of the semiconductor substrate 202 near via and contacts the silicon substrate, i.e., short circuit occurs, the fill factor (F.F.) will be decreased, and hence the efficiency (Eff) of the solar cell will also be decreased.

As shown in Table 1 and FIG. 3, the solar cells in the Experimental Examples have higher fill factors and efficiencies than the solar cell in the Comparative Example, which indicates that the solar cells in the Experimental Examples 1 is superior to the solar cell in the Comparative Example in terms of short circuit prevention. It is further understood from Table 1 that forming the first electrode with a low-lead-content pre-firing electrode does not cause an unfavorable effect to other features of the solar cell. In addition, the photoelectric efficiency of the solar cell is even enhanced.

The disclosed embodiments adopt a low-lead-content pre-firing electrode for forming the first electrode (that is, the intra-via electrode) and a higher-lead-content pre-firing electrode for forming the second electrode without the need for changing the glass frit contents in the pre-firing electrodes. Thus, the fabricated MWT back contact solar cell has one or more of the following advantages:

1. Short circuit does not occur between the first (inter-via) electrode and the semiconductor substrate after the sintering, and the photoelectric efficiency of the solar cell is enhanced effectively.

2. The second electrode and the first electrode have good adhesion to the semiconductor substrate (due to the fact that the glass frit contents in the pre-firing electrodes need not be changed to avoid short circuit), which is beneficial for the following processes, e.g., a wiring process.

3. The second electrode, the third electrode, and the first electrode are formed simultaneously through a co-firing process, so that the fabrication process is simplified and the fabrication cost is reduced.

While the exemplary embodiments disclosed above refer to solar cells of the MWT structure, the principles disclosed herein are applicable to other types of solar cells or to electrical connections in other applications where co-firing of printable electrodes is desirable while certain different requirements (e.g., one electrode should fire-through an insulation layer whereas the other electrode should not) are to be met.

Although the disclosure has been described with reference to the above embodiments, it will be apparent to one of the ordinary skill in the art that modifications to the described embodiment may be made without departing from the spirit of the disclosure. Accordingly, the scope of the disclosure will be defined by the attached claims not by the above detailed descriptions.

What is claimed is:

1. A solar cell structure, comprising:
a semiconductor substrate comprising a first type semiconductor layer having a first side and a second side, a second type semiconductor layer on the first side of the first type semiconductor layer, and at least one via extending through the semiconductor substrate;
a first electrode located in the at least one via, and comprising a glass phase and lead oxide, wherein the lead oxide is present in a first weight percentage amount relative to the weight of the glass phase of the first electrode; and
a second electrode comprising a glass phase and lead oxide, and being partially disposed on the second type semiconductor layer and covering the first electrode, wherein the lead oxide of the second electrode is present in a second weight percentage amount relative to the weight of the glass phase of the second electrode;
wherein the first weight percentage amount is less than the second weight percentage amount.

2. The solar cell structure of claim 1, further comprising
an anti-reflective layer disposed on the second type semiconductor layer.

3. The solar cell structure of claim 1, further comprising
a third electrode disposed on a portion of the second side of the first type semiconductor layer.

4. The solar cell structure of claim 1, wherein at least one of a surface of the semiconductor substrate, or a sidewall of the at least one via is textured.

5. The solar cell structure of claim 1, further comprising
an insulating layer disposed between a sidewall of the at least one via and the first electrode.

6. The solar cell structure of claim 1, wherein the first electrode and the second electrode have the same weight percentage amounts of glass phase relative to the weight of the first electrode and the second electrode, respectively.

7. The solar cell structure of claim 1, wherein the first weight percentage amount is 20 wt % or less.

8. The solar cell structure of claim 1, wherein the first weight percentage amount ranges from 0.1 to 15 wt %.

9. The solar cell structure of claim 1, wherein the second weight percentage amount is greater than 20 wt %.

10. The solar cell structure of claim 1, wherein a surface of the first electrode is substantially coplanar with the first side of the first type semiconductor layer.

11. The solar cell structure of claim 1, wherein the first electrode further covers at least a portion of the second side of the first type semiconductor layer.

12. The solar cell structure of claim 5, wherein the insulating layer comprises silicon nitride.

13. A pre-firing solar cell structure, comprising:
a first type semiconductor substrate having a first side, a second side, and at least one via extending through the first type semiconductor substrate;
a second type semiconductor layer at least partially disposed on the first side of the first type semiconductor substrate;
a pre-firing first electrode located in the at least one via and comprising glass frit and lead oxide, wherein the lead oxide is present in a first weight percentage amount relative to the weight of the glass frit of the pre-firing first electrode;
a pre-firing second electrode comprising glass frit and lead oxide, and being disposed on the second type semiconductor layer and covering the pre-firing first electrode, wherein the lead oxide of the pre-firing second electrode is present in a second weight percentage amount relative to the weight of the glass frit of the pre-firing second electrode; and
an insulating layer at least partially disposed between a sidewall of the at least one via and the pre-firing first electrode;
wherein the first weight percentage amount is less than the second weight percentage amount.

14. The pre-firing solar cell structure of claim 13, further comprising
an anti-reflective layer disposed on the second type semiconductor layer between the pre-firing second electrode and the second type semiconductor layer.

15. A method of making a solar cell structure comprising:
forming at least one via through a first type semiconductor substrate having a first side, a second side, and a second type semiconductor layer on the first side of the first type semiconductor substrate;
forming an insulating layer on a sidewall of the at least one via and the second side of the first type semiconductor substrate;
forming a pre-firing first electrode in the at least one via, the pre-firing first electrode comprising glass frit and lead oxide, wherein the lead oxide is present in a first weight percentage amount relative to the weight of the glass frit of the pre-firing first electrode; and
forming a pre-firing second electrode, comprising glass frit and lead oxide, on the second type semiconductor layer to cover the pre-firing first electrode, wherein the lead oxide of the pre-firing second electrode is present in a second weight percentage amount relative to the weight of the glass frit of the pre-firing second electrode,
wherein the first weight percentage amount is less than the second weight percentage amount.

16. The method of claim 15, wherein the pre-firing first electrode is filled in the at least one via from the second side of the first type semiconductor substrate.

17. The method of claim 15, further comprising:
co-firing the pre-firing first electrode and the pre-firing second electrode to simultaneously sinter the pre-firing first electrode and the pre-firing second electrode into a first electrode and a second electrode, respectively.

18. The method of claim 15, further comprising:
forming a third pre-firing electrode on at least a portion of the second side of the first type semiconductor substrate.

19. The method of claim 18, wherein the third pre-firing electrode comprises aluminum paste.

20. The method of claim 18, further comprising:
co-firing the pre-firing first, second and third electrodes to simultaneously sinter the pre-firing first, second and third electrodes into a first electrode, a second electrode, and a third electrode, respectively.

21. The method of claim 15, wherein the insulating layer comprises silicon nitride.

22. The method of claim 17, wherein the co-firing is at a temperature more than 400° C.

23. The method of claim 15, further comprising:
texturing at least one of the first side of the first type semiconductor substrate, the second side of the first type semiconductor substrate, or the sidewall of the at least one via of the first type semiconductor substrate.

24. The method of claim 15, wherein the second type semiconductor layer is an n-type semiconductor and the first type semiconductor substrate is a p-type semiconductor.

25. The method of claim 15, wherein the second type semiconductor layer is a p-type semiconductor and the first type semiconductor substrate is an n-type semiconductor.

26. The method of claim 15, further comprising
forming an anti-reflective layer on the second type semiconductor layer.
